(19) United States
(12) Patent Application Publication
(10) Pub. No.: US 2015/0155187 A1
(43) Pub. Date: Jun. 4, 2015

(54) ANNULAR BAFFLE FOR PUMPING FROM ABOVE A PLANE OF THE SEMICONDUCTOR WAFER SUPPORT

(71) Applicant: LAM RESEARCH CORPORATION, FREMONT, CA (US)

(72) Inventors: Iqbal Shareef, Fremont, CA (US); Piyush Agarwal, San Jose, CA (US); Jason Augustino, Livermore, CA (US); Andreas Fischer, Castro Valley, CA (US)

(73) Assignee: LAM RESEARCH CORPORATION, FREMONT, CA (US)

(21) Appl. No.: 14/097,108

(22) Filed: Dec. 4, 2013

(51) Int. Cl. H01L 21/67

(52) U.S. Cl. CPC H01L 21/67017

(57) ABSTRACT

A system and method for processing a substrate in a processing chamber and providing an azimuthally evenly distributed draw on the processing byproducts using a gas pump down source coupled to the processing chamber above the plane of a substrate support within the processing chamber. The process chamber can include an annular plenum disposed between the support surface plane and the chamber top, the plenum including at least one vacuum inlet port coupled to the gas pump down source and a continuous inlet gap proximate to a perimeter of the substrate support, the continuous inlet gap having an inlet gas flow resistance of between about twice and about twenty times an outlet gas flow resistance the at least one vacuum inlet port.

### BACKGROUND

The present invention relates generally to semiconductor process tools, and more particularly, to methods and systems for drawing gases away from a process chamber in a semiconductor process tool.

Semiconductor process tools typically include a process chamber formed above a semiconductor wafer support. The processing of the semiconductor wafer (e.g., plasma processing, etching, cleaning, deposition, or any other suitable semiconductor manufacturing process) is conducted within the process chamber.

FIG. 1A is a simplified side cross-sectional view of a typical process chamber system 100. FIG. 1B is a simplified top view of the typical process chamber 101. The typical process chamber system 100 includes the process chamber 101 including top inner surface 103, walls 104 and bottom 105. The top inner surface 103, walls 104 and bottom 105 define the inner surfaces of the process chamber 101. A semiconductor wafer support 102 is also included in the process chamber 101. The semiconductor wafer support 102 supports a semiconductor wafer (not shown) or other suitable substrate for processing in the processing chamber 101.

A gas injection port 110 is included in the process chamber 101. The gas injection port 110 is coupled to one or more process gas sources (not shown) and provides an inlet port for injecting the necessary process gases 111 into the process chamber 101 as may be needed for the desired processing.

The process gases 111 react with the top surface of the semiconductor wafer (not shown) or other substrate for processing in the processing chamber 101 to produce processing byproducts 112. The processing byproducts 112 are then removed from the processing chamber 101 through a gas pump down system 120. An inlet 122 to the gas pump down system 120 is typically located below the plane 118 of the surface of the semiconductor wafer support 102. Thus drawing the processing byproducts 112 downward and off the perimeter of the semiconductor wafer support 102.

The inlet 122 to the gas pump down system 120 is typically located approximately central to the processing chamber 101 and underneath the semiconductor wafer support 102. Centrally locating the inlet 122 to the gas pump down system 120 in the bottom 105 of the processing chamber 101 provides a generally even distribution of a draw on the processing byproducts 112 from every location around the perimeter of the semiconductor wafer support 102. This even distribution of the draw on the processing byproducts 112 is referred to as an azimuthally even distribution. The azimuthally even distribution of the draw helps ensure an azimuthally even processing of the surface of the semiconductor wafer being processed. Asymmetries can also be caused by restrictions of the flow of the process gases proximate to the perimeter of the semiconductor wafer support 102 such as may be caused by adjacent structures and the interior shape of the processing chamber 101.

Unfortunately some arrangements of the process chamber 101 and the semiconductor wafer support 102 may not allow a centrally located inlet 122 to the gas pump down system 120 or even alloy the inlet to be located in the bottom of the process chamber. A non-centrally located inlet to the gas pump down system 120 causes a non-uniform draw and corresponding nonuniform distribution of the process gases 111 and the processing byproducts 112. Typically the process gases 111 and the processing byproducts 112 become concentrated near the non-centrally located vacuum inlet. As a result, the surface of the semiconductor wafer being processed is non-uniformly processed such that some portions of the surface are processed more or less than other portions of the surface.

What is needed is a system and method for producing an azimuthally evenly distributed draw on the byproducts around the perimeter of the semiconductor wafer support from a non-centrally located inlet to the gas pump down system.

### SUMMARY

Broadly speaking, the present invention fills these needs by is a system and method for producing an azimuthally evenly distributed draw on the byproducts around the perimeter of the semiconductor wafer support from a non-centrally located inlet to the gas pump down system. The present invention also includes systems and methods of pumping out the process gases from above the wafer plane. It should be appreciated that the present invention can be implemented in numerous ways, including as a process, an apparatus, a system, computer readable media, or a device. Several inventive embodiments of the present invention are described below.

One embodiment provides a system for processing a substrate in a processing chamber and providing an azimuthally evenly distributed draw on the processing byproducts using a gas pump down source coupled to the processing chamber above the plane of a substrate support within the processing chamber. The process chamber can include an annular plenum disposed between the support surface plane and the chamber top, the plenum including at least one vacuum inlet port coupled to the gas pump down source and a continuous inlet gap proximate to a perimeter of the substrate support, the continuous inlet gap having an inlet gas flow resistance of between about twice and about twenty times an outlet gas flow resistance the at least one vacuum inlet port.

The at least one vacuum inlet port can include at two or more vacuum inlet ports. The two or more vacuum inlet ports can be unevenly or substantially evenly distributed around the perimeter of the annular plenum.

The annular plenum can be included in the chamber top and/or the chamber sides. The annular plenum can be formed by an extension extending from the chamber top and toward the chamber sides and the continuous inlet gap can be formed between the extension and the chamber sides. The annular plenum can also be disposed between the chamber top and a plane of the substrate support.

Another embodiment provides a method of flowing gases through a processing chamber including inputting a gas flow into the processing chamber, distributing the gas flow in a substantially even azimuthal distribution from the center portion of the top of the processing chamber to a continuous inlet gap disposed near a perimeter of the processing chamber wherein the continuous inlet gap has a gas flow resistance of at least twice a gas flow resistance of at least one vacuum inlet port disposed in the top of the processing chamber. The continuous inlet gap is disposed between a substrate support plane and the processing chamber top. The continuous inlet gap is fluidly coupled to an annular plenum, the annular plenum including the at least one vacuum inlet port, the at least one vacuum inlet port being coupled to a gas pump down source capable of drawing the gas flow out of the processing chamber, through the continuous inlet gap, into the annular plenum and out through the at least one vacuum inlet port.

Other aspects and advantages of the invention will become apparent from the following detailed description, taken in conjunction with the accompanying drawings, illustrating by way of example the principles of the invention.

### BRIEF DESCRIPTION OF THE DRAWINGS

The present invention will be readily understood by the following detailed description in conjunction with the accompanying drawings.

FIG. 1A is a simplified side cross-sectional view of a typical process chamber system.

FIG. 1B is a simplified top view of the typical process chamber.

FIG. 1C is an integrated process tool cluster, for implementing embodiments of the present disclosure.

FIG. 1D is a simplified side cross-sectional view of a process chamber system with a non centrally located inlet to the gas pump down system, for implementing embodiments of the present disclosure.

FIG. 1E is a simplified top view of the process chamber, for implementing embodiments of the present disclosure.

FIG. 2A is a perspective view of a processing chamber system, for implementing embodiments of the present disclosure.

FIG. 2B is a cross-section of the perspective view of the processing chamber system, for implementing embodiments of the present disclosure.

FIG. 2C is a cross-section side view of the processing chamber, for implementing embodiments of the present disclosure.

FIG. 2D is a cross-section top view of the processing chamber, for implementing embodiments of the present disclosure

FIG. 2E is a cross-section top view of an alternative processing chamber, for implementing embodiments of the present disclosure.

FIG. 2F is a perspective view of an alternative processing chamber system, for implementing embodiments of the present disclosure.

FIG. 2G is a cross-section top view of a second alternative processing chamber, for implementing embodiments of the present disclosure.

FIG. 2H is a phantom cross-section view of the second alternative processing chamber, for implementing embodiments of the present disclosure.

FIGS. 3A and 3B are gas flow velocity diagrams of the gas flow in the process chamber system, for implementing embodiments of the present disclosure.

FIG. 4 is a cross-section view of the alternative processing chamber, for implementing embodiments of the present disclosure.

FIG. 5 is a cross-section view of a third alternative processing chamber, for implementing embodiments of the present disclosure.

FIG. 6 is a cross-section view of a third alternative processing chamber, for implementing embodiments of the present disclosure.

FIG. 7 is a flowchart diagram that illustrates the method operations performed in masking the location of a vacuum port, for implementing embodiments of the present disclosure.

FIG. 8 is a simplified block diagram of the processing chamber system 800, for implementing embodiments of the present disclosure.

FIG. 9 is a simplified schematic diagram of a computer system 900, for implementing embodiments of the present disclosure.

### DETAILED DESCRIPTION

Several exemplary embodiments for is systems and methods for producing an azimuthally evenly distributed draw on the byproducts around the perimeter of the semiconductor wafer support from a non-centrally located inlet to the gas pump down system will now be described. Systems and methods of pumping out the process gases from above the wafer plane will also be described. It will be apparent to those skilled in the art that the present invention may be practiced without some or all of the specific details set forth herein.

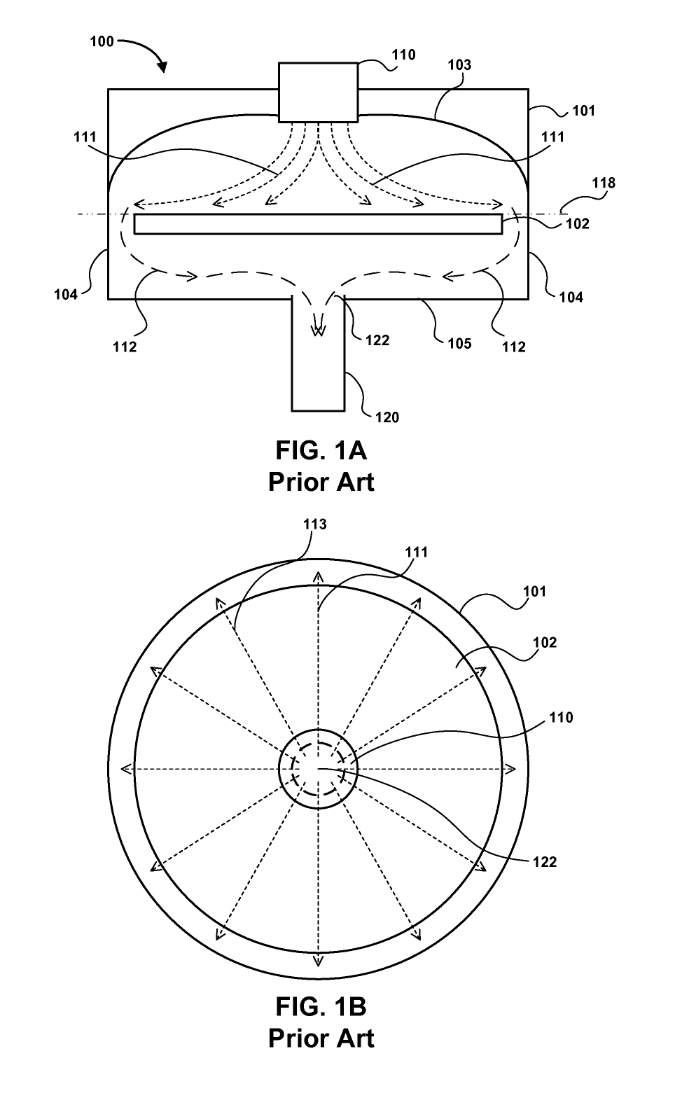

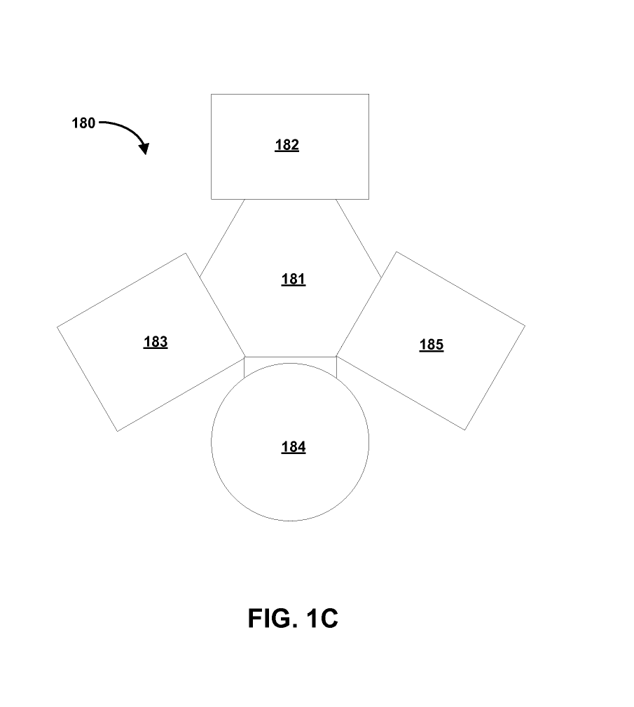

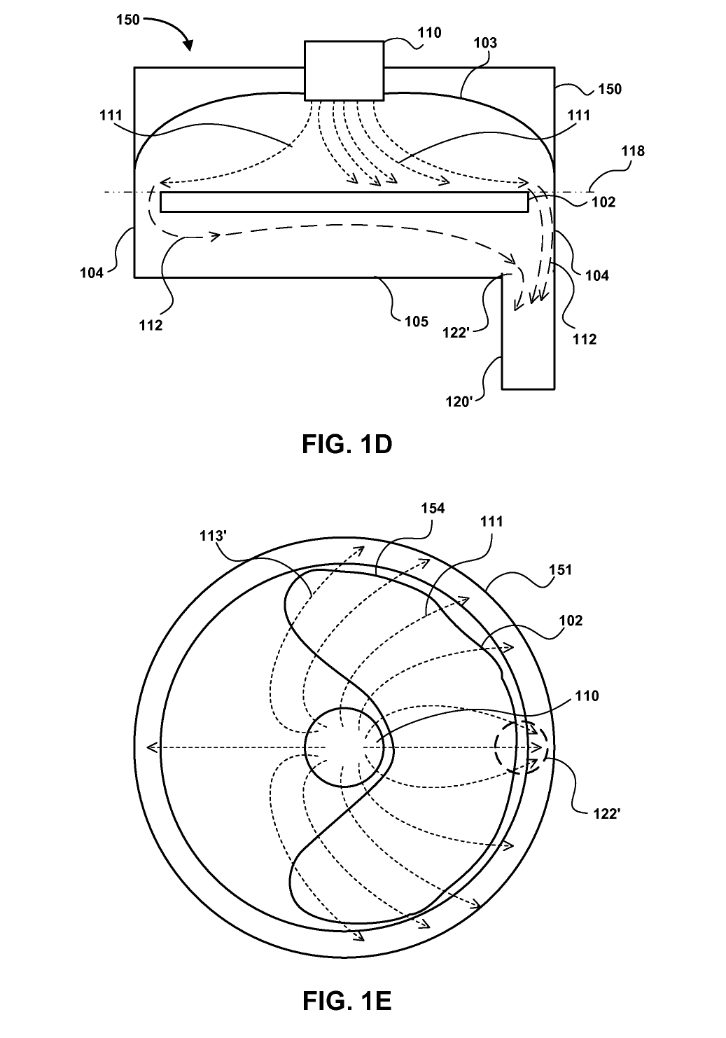

An integrated strip allows the etch and strip process tools to process semiconductor wafers in an integrated fashion without removing the semiconductor wafers from the process tools instead of processing in a “batch mode.” As a result, the integrated strip provides for increased efficiency and semiconductor wafer throughput. FIG. 1C is an integrated process tool cluster 180, for implementing embodiments of the present disclosure. The integrated process tool cluster 180 includes a common transfer or cluster chamber 181, a load port 182 and multiple process tools such as an etch tool 183, a strip tool 184, a cleaning tool 185, or other process tools as may be desired.

The integrated strip is possible as the etch 183 and strip 184 processing tools are coupled to the cluster chamber 181. However, space constraints on the cluster chamber 181 do not allow gas pumping from underneath the semiconductor wafer support, leading to non-uniform azimuthal flow distribution and the corresponding azmuthal non-uniformity of the processing of the semiconductor wafer as described in more detail below.

FIG. 1D is a simplified side cross-sectional view of a process chamber system 150 with a non centrally located inlet 122′ to the gas pump down system 120, for implementing embodiments of the present disclosure. FIG. 1E is a simplified top view of the process chamber 151, for implementing embodiments of the present disclosure. A non-centrally located inlet 122′ to the gas pump down system 120 causes the flow 113′ of process gases 111 and the processing byproducts 112 to be concentrated near the non-centrally located vacuum inlet 122′. The concentrated flow 113′ of processing gases 111 and process byproducts is an azimuthally uneven distribution of the draw on the byproducts around the perimeter of the semiconductor wafer support 102, as shown in FIG. 1E. The azimuthally uneven distribution 113′ of the draw on the process gases 111 and the process byproducts 112 around the perimeter of the semiconductor wafer support 102 causes corresponding azimuthal nonuniformities 154 in the processing of the semiconductor wafer.

Adding multiple inlets to the gas pump down system results in multiple locations of concentrated flow byproducts resulting in multiple uneven distributions of the draw on the byproducts around the perimeter of the semiconductor wafer support. Corresponding multiple azimuthal process nonuniformities are caused by the corresponding uneven processing of the semiconductor wafer.

One implementation provides for a system and method of top pumping through an annular, 360 degree inlet that can be located above, even with or below a semiconductor wafer support plane. The annular, 360 degree inlet forces gases to be drawn away from the perimeter of the semiconductor wafer support, in an azimuthally evenly distributed flow. The annular, 360 degree inlet can include an annular plenum having a relatively narrow, annular inlet gap proximate to an outer perimeter of the semiconductor wafer support. The annular plenum is coupled to one or more top pumping inlet ports to the gas pump down system. The narrow annular inlet gap creates sufficient flow resistance to mask the flow concentration effects of one or more top pumping inlet ports, as shown in FIGS. 1D and 1E above, to achieve azimuthal flow and process uniformity.

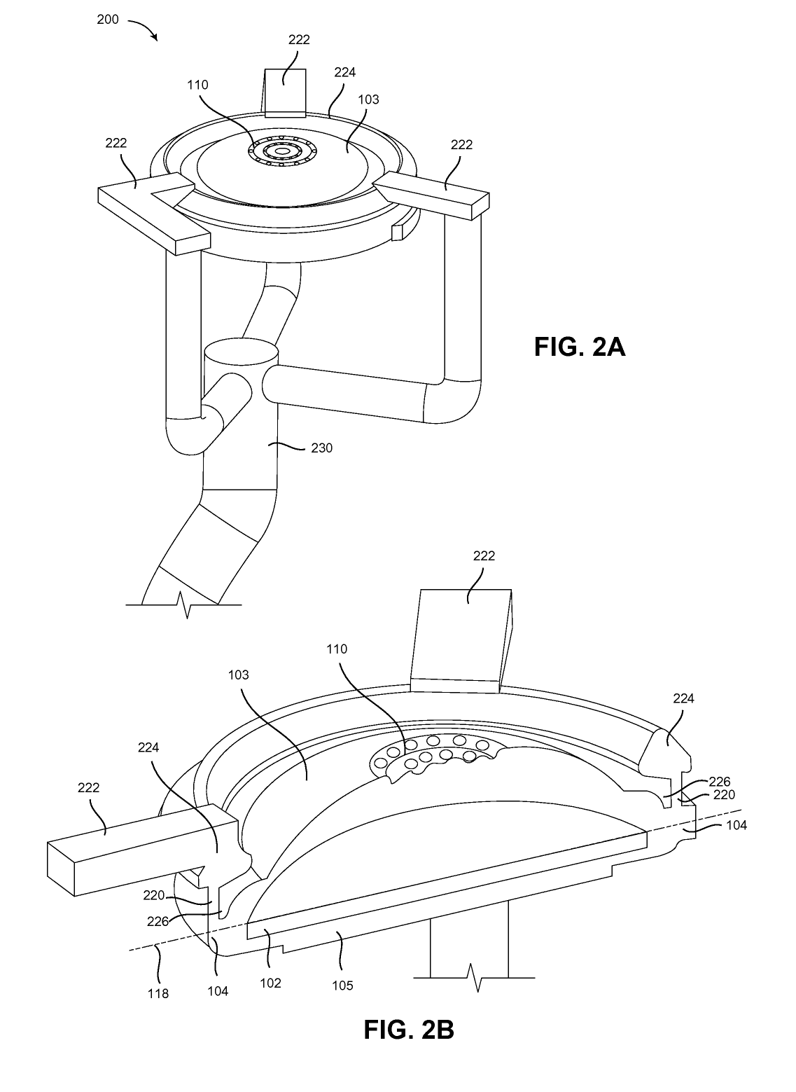

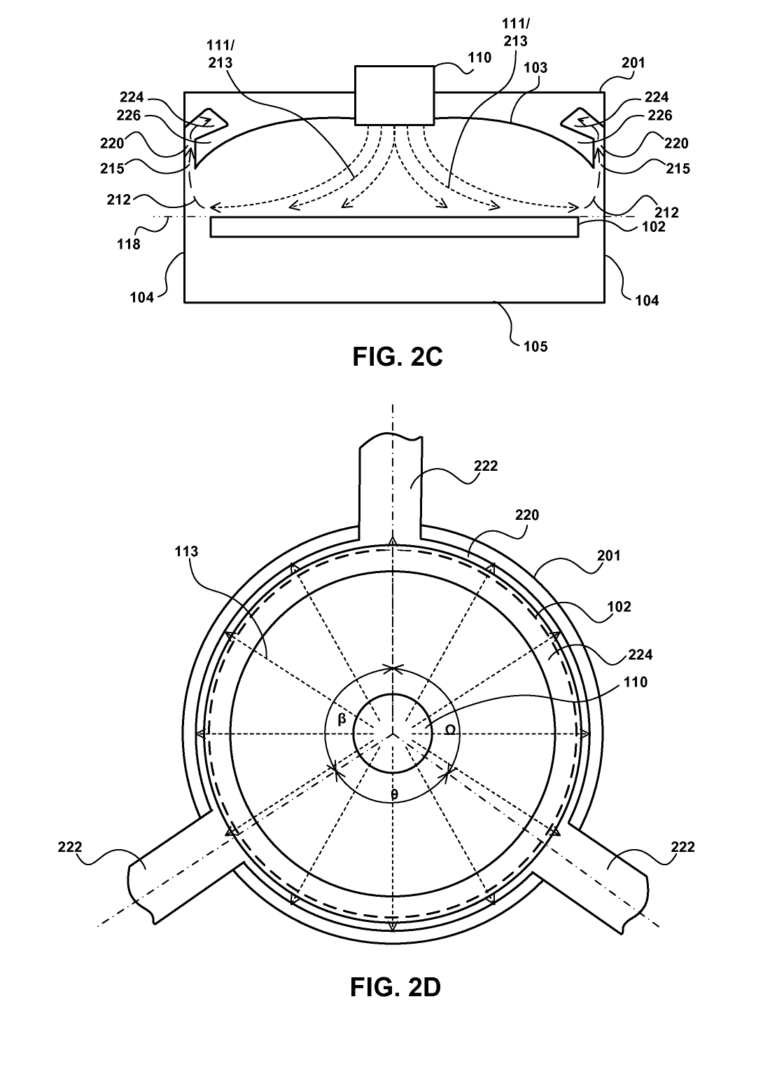

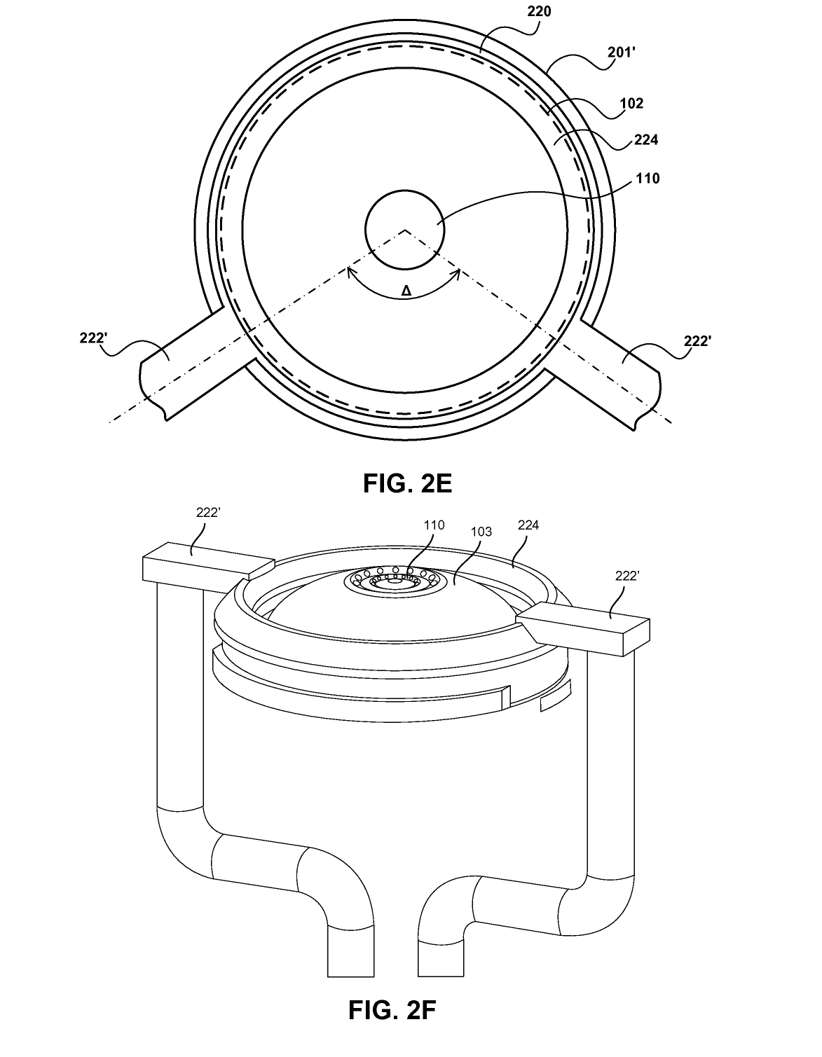

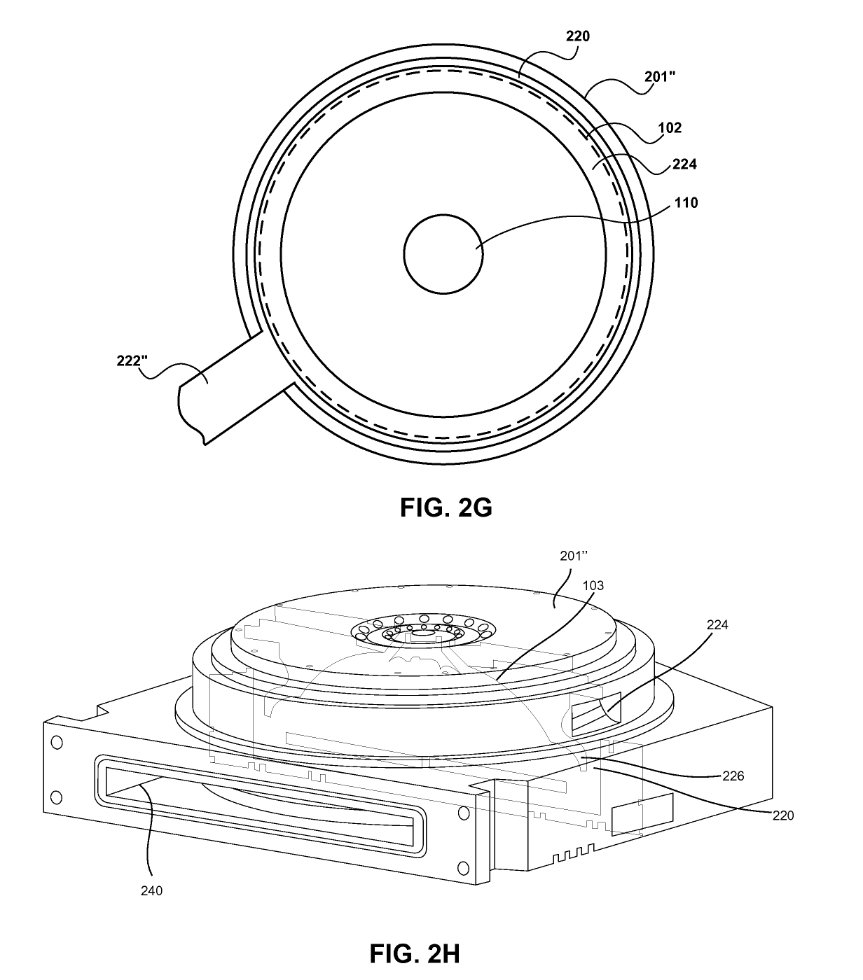

FIG. 2A is a perspective view of a processing chamber system 200, for implementing embodiments of the present disclosure. FIG. 2B is a cross-section of the perspective view of the processing chamber system 200, for implementing embodiments of the present disclosure. The processing chamber system 200 includes a process chamber 201 including a gas injection port 110 approximately centrally located in a top inner surface 103. The process chamber 201 also includes walls 104, a bottom 105 and a semiconductor wafer support 102. The process chamber 201 also includes an annular plenum 224. The annular plenum 224 is coupled to the processing volume 202 by a 360 degree inlet gap 220. The annular plenum 224 is also coupled to one or more top pumping vacuum inlet ports 222 to the gas pump down system 230.

FIG. 2C is a cross-section side view of the processing chamber 201, for implementing embodiments of the present disclosure. FIG. 2D is a cross-section top view of the processing chamber 201, for implementing embodiments of the present disclosure. The process gases 111 are injected through the injection port 110 in an azimuthally distributed flow 213 across the surface to be processed and toward the inlet gap 220. The gas pump down system 230 draws the processing byproducts 212 into the inlet gap 220 in an azimuthally evenly distributed flow 215 and into the annular plenum 224. The gas pump down system 230 draws the azimuthally evenly distributed flow 215 into the vacuum inlet ports 222.

The annular plenum 224 can be formed as a space within the chamber top as shown in FIG. 2C. By way of example the annular plenum 224 can be formed by adding an extension 226 to the top inner surface 103. It should be understood that while the annular plenum 224 is shown having a substantially triangular cross-section shape, any suitable cross-section shape such as rectangular, rounded, oval or other shape can be used.

The inlet gap 220 provides a substantially uniform draw azimuthally around the perimeter of the inlet gap to substantially eliminate any localized flow concentrations near the vacuum inlet ports 222. The inlet gap 220 includes a flow resistance to the azimuthally evenly distributed flow 215 greater than a flow resistance at any one of the inlet ports 222. By way of example, the inlet gap 220 can have a flow resistance of about twice the flow resistance at any one of the vacuum inlet ports 222. Alternatively, the inlet gap 220 can have a flow resistance of between about five and about ten times the flow resistance at any one of the vacuum inlet ports 222. As the flow resistance provided by the vacuum inlet gap 220 increases, the flow 215 becomes increasingly azimuthally evenly distributed such that the gas flow varies between about 0.0 meters per second and about 0.6 meters per second between locations around the perimeter of the inlet gap 220.

However, as the flow resistance provided by the inlet gap 220 increases the gas flow 215 velocity at the entry to the inlet gap also increases. As the flow resistance of the inlet gap 220 is increasing, the minimum pressure inside the processing chamber is also increasing also for a given gas flow. This increased minimum pressure can result in undesirable process variations and also results in increased process gas consumption and corresponding increase in operating costs. As the gas flow 215 velocity increases then turbulence can also increase. The turbulence can then cause disruptions in the azimuthally even distribution. By way of example, the flow resistance provided by the inlet gap 220 is selected to increase the gas flow 215 velocity to a velocity that is less than or about equal to the gas flow velocity of the process gases 111 at the injection port 110. It should be understood that in some process chamber configurations and processes the may allow or tolerate higher gas flow 215 velocities at the inlet gap 220. Alternatively, some process chamber configurations and processes the may not allow or tolerate higher gas flow 215 velocities at the inlet gap 220. Thus the precise gas flow 215 velocity at the inlet gap 220 is dependent on the selected process conducted within the process chamber and also dependent on the configuration (e.g., shape and arrangement) of the various components within the process chamber.

The three vacuum inlet ports 222 can be substantially evenly distributed around the perimeter of the annular plenum 224 (e.g., angles β, θ and α are equal at about 120 degrees each). Alternatively, the three vacuum inlet ports 222 can be unevenly distributed around the perimeter of the annular plenum 224. For example, angle β can be about 90 degrees while angle θ and α can be about 120 degrees and 150 degrees, respectively. These values of the angles β, θ and α are merely exemplary and it should be understood that the angles β, θ and α can be any suitable dimension as may be required by the structure and space limitations of the chamber system 200.

FIG. 2E is a cross-section top view of an alternative processing chamber 201′, for implementing embodiments of the present disclosure. FIG. 2F is a perspective view of an alternative processing chamber system 200′, for implementing embodiments of the present disclosure. The processing chamber 201′ is substantially similar to the processing chamber 201 described above. However, the processing chamber 201′ has only two vacuum inlet ports 222′. The two vacuum inlet ports 222′are separated by angle Δ having a range of between about 90 degrees and about 180 degrees. The precise measure of the separation angle Δ is not critical as the annular plenum 224 and the inlet gap 220 evenly distribute the draw of the two vacuum inlet ports 222′, thus masking the relative locations of the ports from the surface being processed.

FIG. 2G is a cross-section top view of a second alternative processing chamber 201″, for implementing embodiments of the present disclosure. FIG. 2H is a phantom cross-section view of the second alternative processing chamber 201″, for implementing embodiments of the present disclosure. The second alternative processing chamber 201″ is substantially similar to the processing chamber 201 described above. However, the second alternative processing chamber 201″ has only one vacuum inlet port 222″. The annular plenum 224 and the inlet gap 220 evenly distribute the draw of the vacuum inlet port 222″, thus masking the relative location of the port from the surface being processed.

A load port 240 is also included in the second alternative processing chamber 201″. A load port 240 is also provided in each of the above processing chambers 201, 201′. The load port 240 provides access to load (i.e., insert) and unload (i.e., remove) the semiconductor wafer, or other suitable substrate, to be processed in the processing chamber 201, 201′, 201″. The location of the load port 240 on the processing chambers 201, 201′, 201″ may also prevent the vacuum inlet ports 222, 222′ from being evenly distributed around the perimeter of the annular plenum 224. Thus, in at least one embodiment, the load port may generate the need for the masking effects of the annular plenum 224 and the inlet gap 220.

It should be understood that the vacuum inlet ports 222′ and 222″ may be sized differently than the vacuum inlet ports 222. By way of example, vacuum inlet ports 222′ may be larger than vacuum inlet ports 222 so that the two vacuum inlet ports 222′ can draw the same flow rate while having the same flow restriction as the three vacuum inlet ports 222. Similarly, the single vacuum inlet port 222″ may be sized larger than the two vacuum inlet ports 222′ so as to provide the same flow rate while having the same flow restriction as the three vacuum inlet ports 222. It should also be understood that any suitable cross-sectional shape (round, triangular, oval, rectangular, etc.) of the vacuum inlet ports 222 can be utilized.

While embodiments having one, two and three vacuum inlet ports are described herein, it should be understood that more than three vacuum inlet ports could also be included in the processing chamber 201. It should also be noted that each of the multiple vacuum inlet ports 222, 222′ may be sized differently than remaining vacuum inlet ports so as to select the flow restriction in each of the vacuum inlet ports as may be required by the structure and space limitations of the process chamber system 200.

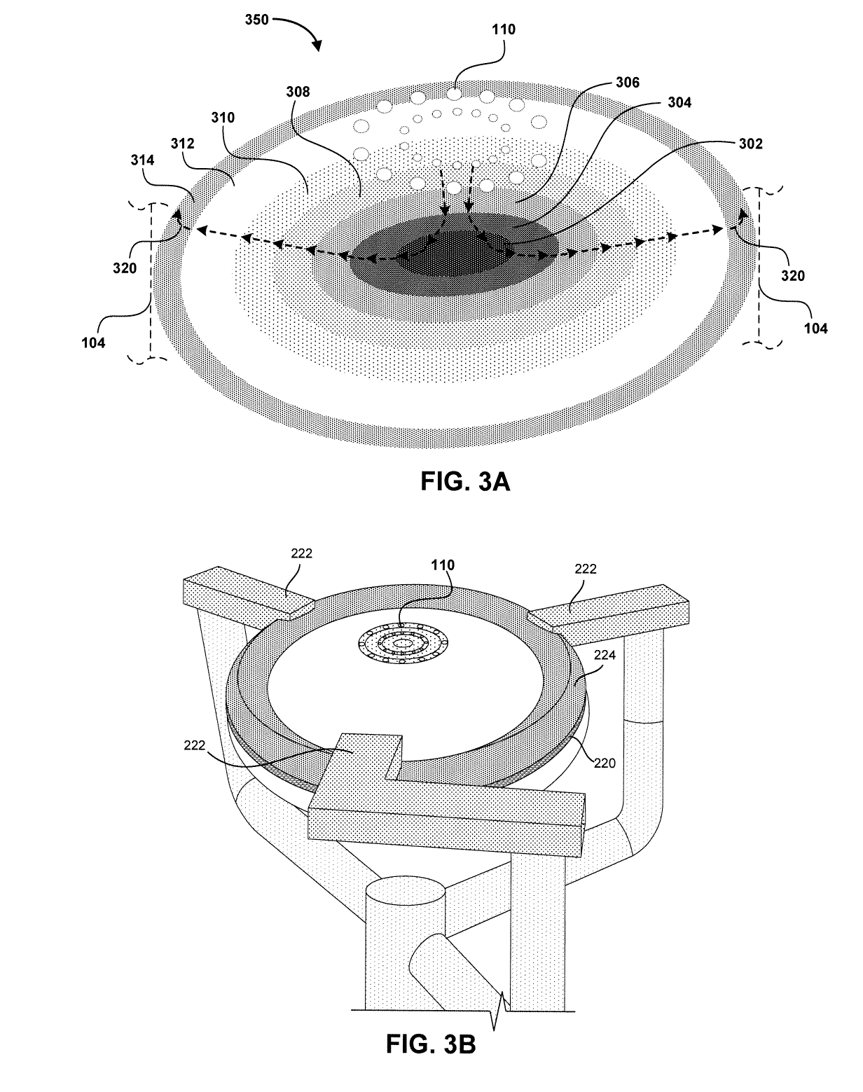

FIGS. 3A and 3B are process gas flow velocity diagrams of the process gas flow 320 in the process chamber system 200, for implementing embodiments of the present disclosure. As shown in FIG. 3A, the gas flow 320 velocity shown in a central region 302 corresponds to the area in closest proximity to the injection ports 110. The gas flow 320 velocity gradually slows as the gas flow spreads radially outward, toward the inner wall 104 of the process chamber. The successively lighter filled regions 302-312 each indicate a slower gas flow 320 velocity than the region closer to the inlet port 110.

By way of example, the gas flow 320 velocity in region 304 is slower than the gas flow velocity in region 302. Similarly, the gas flow velocity drops further in each successive annular regions 304-312.

The outermost annular region 314 is proximate to the inlet gap 220 (not shown). When the gas flow 320 arrives at the outermost annular region 314, the gas flow velocity drastically increases as a result of the draw from the gas pump down source 230 as distributed by the annular plenum 224 and the inlet gap 220.

Referring now to FIG. 3B, the gas flow velocity in the annular plenum 224 is shown as being slower (i.e., lighter color) than the gas flow velocity in the inlet gap 220. The gas flow velocity in the annular plenum 224 is slower than the gas flow velocity in the inlet gap 220 due to the larger volume of the annular plenum as compared to the inlet gap. The larger volume allows the gas flow to velocity to decrease inside the annular plenum 224. Lowering the gas flow velocity in the annular plenum 224 aids in masking the location of the vacuum inlet ports 222 from the process chamber which allows the annular plenum and the inlet gap 220 to apply an azimuthally even draw on the gases in the processing chamber near the inner wall of the processing chamber.

The gas flow velocity can further decrease as the gas flows from the annular plenum 224 and into the vacuum inlet ports 222 to further aid in masking the location of the vacuum inlet ports from the process chamber. As described elsewhere in more detail, the gas flow velocity in the vacuum inlet ports 222 is about one half or less than the gas flow velocity in the inlet gap 220. The lower gas flow velocity in the vacuum inlet ports 222 masks the location of the vacuum inlet ports from the process chamber which allows the annular plenum 224 and the inlet gap 220 to apply an azimuthally even draw on the gases in the processing chamber near the inner wall of the processing chamber.

The relative volumes of the annular plenum 224 and into the vacuum inlet ports 222 determine the gas flow velocity. If the volume of the vacuum inlet ports 222 is greater than the volume of the annular plenum 224, then the gas flow velocity will decrease. Alternatively, if the volume of the vacuum inlet ports 222 is less than the volume of the annular plenum 224, then the gas flow velocity will increase. If the volume of the vacuum inlet ports 222 is about equal to the volume of the annular plenum 224, then the gas flow velocity will remain substantially constant.

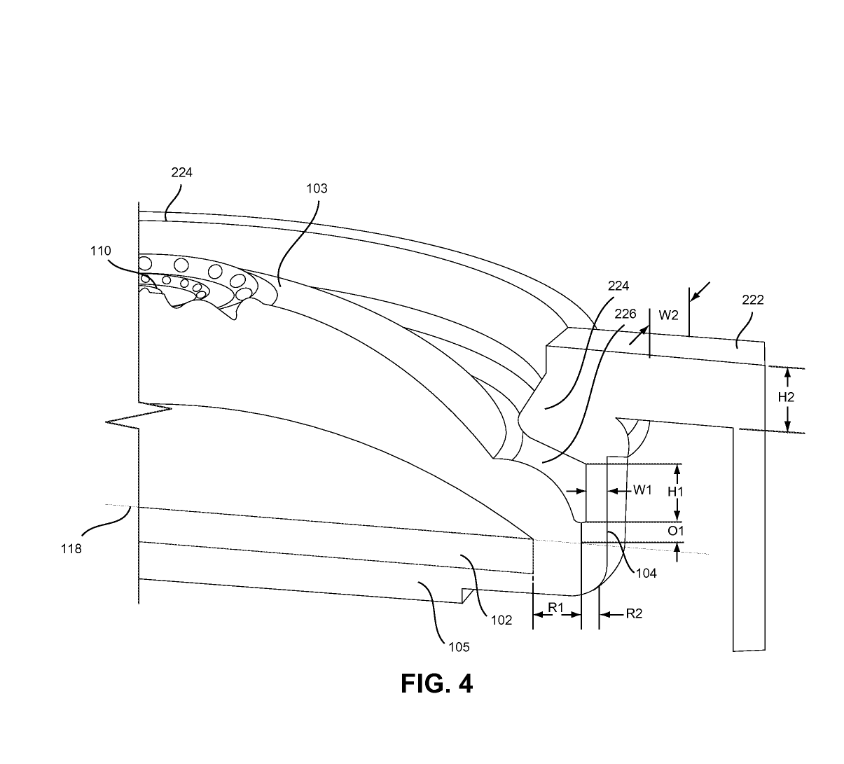

FIG. 4 is a cross-section view of the alternative processing chamber 201′, for implementing embodiments of the present disclosure. The width W1 of the inlet gap 220 can be between about 3 millimeters and about 12 millimeters. Height H1 of the inlet gap 220 can be between about 20 millimeters and about 40 millimeters. Offset O1 of the inlet gap 220 from the plane 118 of the substrate support 102 can be between about 3 millimeters and about 20 millimeters. Radial offset R1 of the inlet gap 220 from the perimeter of the semiconductor wafer support 102 can be between about 15 millimeters and about 30 millimeters. A radial offset R2 of the inlet gap 220 from the walls 104 of the processing chamber can be between about 0 millimeters and about 20 millimeters. The width W2 of the vacuum inlet ports 222 can be between about 25 millimeters and about 50 millimeters. Height H2 of the vacuum inlet ports 222 can be between about 25 millimeters and about 50 millimeters.

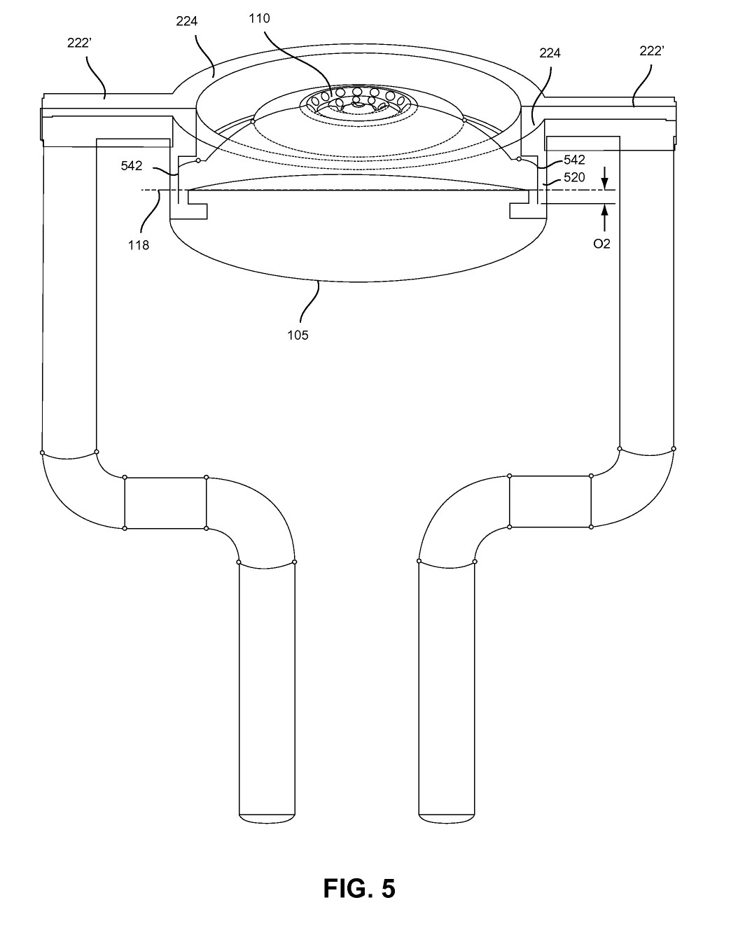

FIG. 5 is a cross-section view of a third alternative processing chamber 501, for implementing embodiments of the present disclosure. The processing chamber 501 is substantially similar to the processing chambers 201, 201′, 201″ described above however, the opening to the inlet gap 520 has an offset O2 below the plane 118 of the substrate support 102. An extension 542 can be included to extend the opening to the inlet gap 520 to below the plane 118. Extending the opening to the inlet gap 520 to below the plane simulates the effects of bottom pumping as described in FIGS. 1A and 1B above but utilizing a top drawing and top of the process chamber connections to the gas pump down system. The offset O2 can be between about 0 millimeters (e.g., even with the plane 118) and about 20 millimeters below the plane 118.

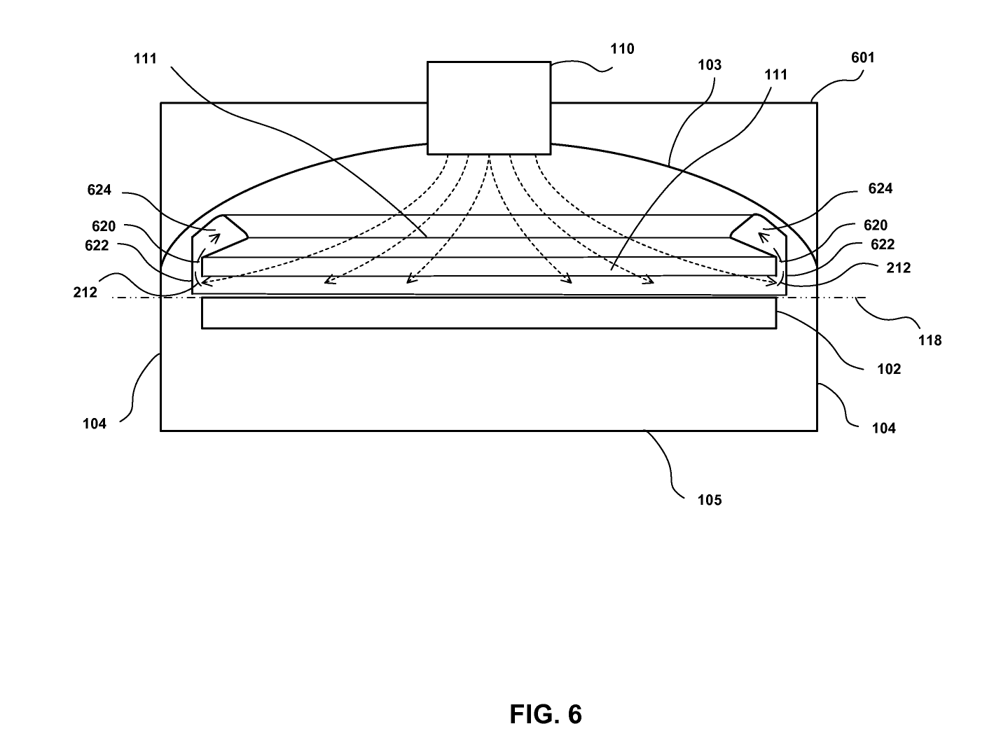

FIG. 6 is a cross-section view of a third alternative processing chamber 601, for implementing embodiments of the present disclosure. The processing chamber 601 is substantially similar to the processing chambers 201, 201′, 201″, 501 described above however, the annular plenum 624 is disposed between the inner top surface 103 and the plane 118 of the substrate support 102. Placing the annular plenum 624 between the inner top surface 103 and the plane 118 of the substrate support 102 may allow the annular plenum to be more easily added to existing process chamber designs. Further, forming the annular plenum 624 separate from the inner top surface 103 or the chamber top or the chamber walls 104 can allow the annular plenum position to be moved from one of multiple locations such as moving the annular plenum and the inlet gap closer to or further away from or above or below the plane 118. Further, the annular plenum 624 can be removed from the process chamber 601 such as may be needed to reconfigure the process chamber for a different process or for service (e.g., cleaning, repair, etc.) of the processing chamber or the annular plenum. The annular plenum 624 can also include extension similar to extensions 542 shown and discussed in FIG. 5 above.

The annular plenum 624 and the inlet gap 620 can be formed from a metal (e.g., aluminum or steel or alloys thereof, etc.). Alternatively, the annular plenum 624 and the inlet gap 620 can be formed from a suitable ceramic material (e.g., quartz, glass, alumina, etc.). Forming the annular plenum 624 separately from the sides 104 and top 103 of the process chamber 601 allows a different material and to be utilized in the annular plenum 624 than in the other portions of the process chamber and other structures included within the process chamber.

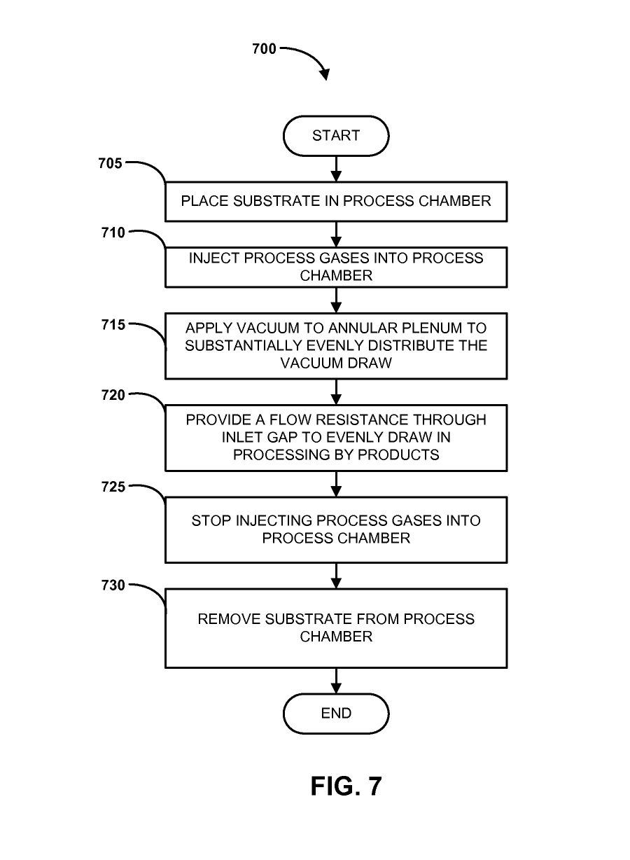

FIG. 7 is a flowchart diagram that illustrates the method operations 700 performed in masking the location of a vacuum port, for implementing embodiments of the present disclosure.

In an operation 705, one or more substrates are placed in the processing chamber for processing and the process chamber is closed for processing. Referring to the cluster type tools in FIG. 1C above, the substrate can be being transferred through the cluster chamber 181 from the load port 182 or from one of the other processing chambers 183-185.

In an operation 710, one or more process gases are injected into the processing chamber and the processing of the substrates begins. The processing of the substrates may also include applying the required biasing currents and RF to one or more electrodes (e.g., top inner surface 103 and/or substrate support 102) within the processing chamber.

In an operation 715, a gas pump down source is applied to an annular plenum 224, 524, 624 though one or more vacuum inlet ports 222, 222′, 222″. The annular plenum substantially evenly distributes the draw of the one or more vacuum inlet ports 222, 222′, 222″ to the inlet gap 220, 520, 620 near the perimeter of the substrate support 102.

In an operation 720, the inlet gap 220, 520, 620 draws processing byproducts into the annular plenum in an azimuthally evenly distributed draw off the perimeter of the surface being processed. The annular gap provides a flow resistance sufficient to mask the locations of the one or more vacuum inlet ports 222, 222′, 222″.

In an operation 725, the processing of the substrate surface is completed and the process gas flows and biasing current and RF can be terminated. The substrate can then be removed from the processing chamber, in an operation 730, and the method operations can end.

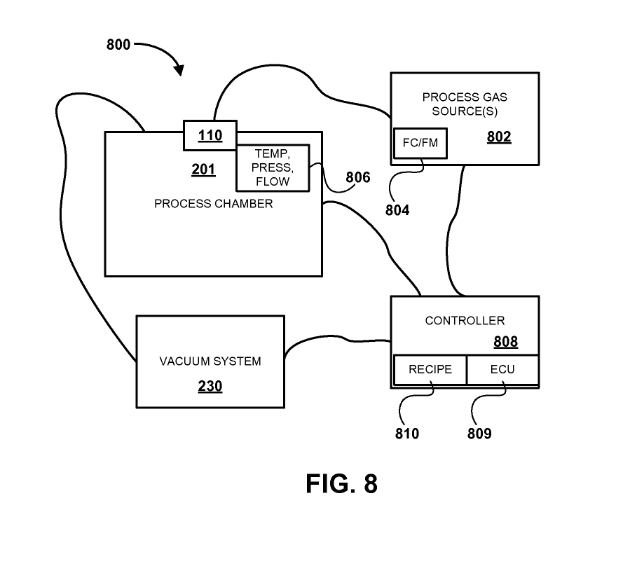

FIG. 8 is a simplified block diagram of the processing chamber system 800, for implementing embodiments of the present disclosure. The processing chamber system 800 includes a processing chamber such as processing chambers 201-601 described above. The gas pump down system 230 is coupled to the processing chamber though the chamber top 103 or top portions of the sides 104 of the processing chamber.

One or more process gas sources 802 are also coupled to the inlet port 110 of the processing chamber. The process gas sources 802 also include any necessary flow controllers, flow meters, valves, manifolds, mixers and pressure controllers 804 as may be needed to deliver the process gases to the processing chamber.

A controller 808 is also included in the processing chamber system 800. The controller 808 is coupled to control inputs and instrumentation outputs 806, 804 on each of the process gas sources 802, the processing chamber and the gas pump down system 230. The controller 808 includes an electronic control unit 809 for monitoring and controlling the processing chamber system 800. The controller 808 also includes one or more recipes in an electronically executable form for controlling and monitoring the operations of the processing chamber system 800.

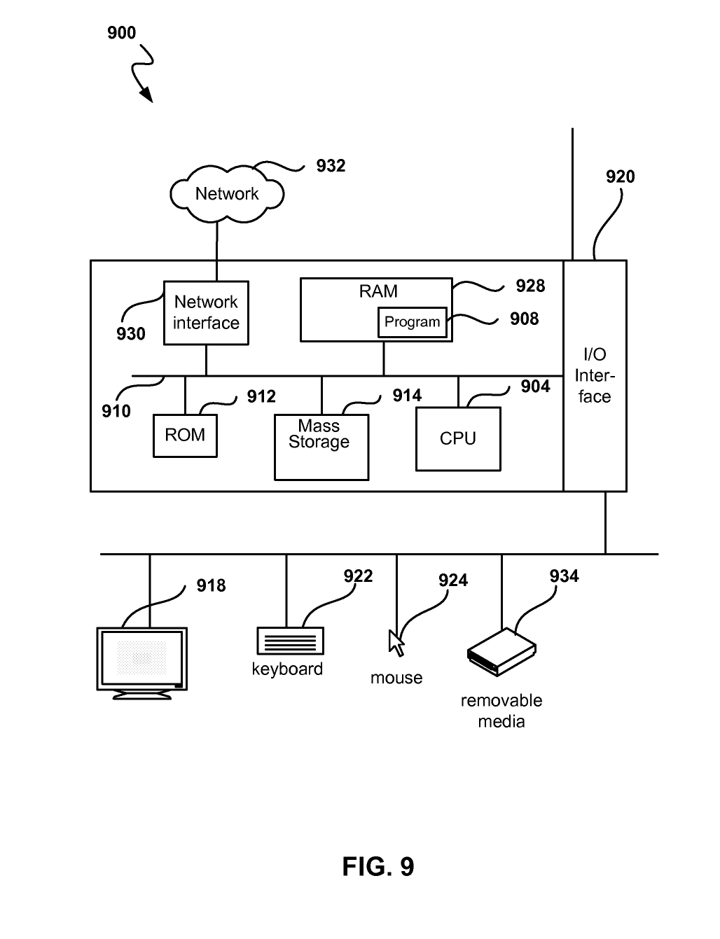

FIG. 9 is a simplified schematic diagram of a computer system 900, for implementing embodiments of the present disclosure. FIG. 9 depicts an exemplary computer environment for implementing embodiments of the invention such as controller ECU 809. It should be appreciated that the methods described herein may be performed with a digital processing system, such as a conventional, general-purpose computer system. Special purpose computers, which are designed or programmed to perform only one function, may be used in the alternative.

The computer system 900 includes a central processing unit 904, which is coupled through a bus 910 to memory 928, mass storage 914, and Input/Output (I/O) interface 920. Mass storage 914 represents a persistent data storage device such as a hard drive or a USB drive, which may be local or remote. Network interface 930 provides connections via one or more networks such as the Internet 932, allowing communications (wired or wireless) with other devices. It should be appreciated that CPU 904 may be embodied in a general-purpose processor, a special purpose processor, or a specially programmed logic device.

Input/Output (I/O) interface 920 provides communication with different peripherals and is connected with CPU 904, memory 928, and mass storage 914, through the bus 910. Sample peripherals include display 918, keyboard 922, mouse 924, removable media device 934, etc.

Display 918 is configured to display the user interfaces described herein. Keyboard 922, mouse 924, removable media device 934, and other peripherals are coupled to I/O interface 920 in order to exchange information with CPU 904. It should be appreciated that data to and from external devices may be communicated through I/O interface 920. Embodiments of the invention can also be practiced in distributed computing environments where tasks are performed by remote processing devices that are linked through a wired or a wireless network.

Embodiments of the present invention can be fabricated as computer readable code on a non-transitory computer readable storage medium. The non-transitory computer readable storage medium holds data which can be read by a computer system. Examples of the non-transitory computer readable storage medium include permanent storage 908, network attached storage (NAS), read-only memory or random-access memory in memory module 928, Compact Discs (CD), Blu-ray™ discs, flash drives, hard drives, magnetic tapes, and other data storage devices. The non-transitory computer readable storage medium may be distributed over a network coupled computer system so that the computer readable code is stored and executed in a distributed fashion.

Some, or all operations of the method presented herein are executed through a processor, such as CPU 904 of FIG. 9. Additionally, although the method operations were described in a specific order, it should be understood that some operations may be performed in a different order, when the order of the operations do not affect the expected results. In addition, other operations may be included in the methods presented, and the operations may be performed by different entities in a distributed fashion, as long as the processing of the operations is performed in the desired way.

In addition, at least one operation of some methods performs physical manipulation of physical quantities, and some of the operations described herein are useful machine operations. Embodiments presented herein recite a device or apparatus. The apparatus may be specially constructed for the required purpose or may be a general purpose computer. The apparatus includes a processor capable of executing the program instructions of the computer programs presented herein.

Although the foregoing invention has been described in some detail for purposes of clarity of understanding, it will be apparent that certain changes and modifications may be practiced within the scope of the appended claims. Accordingly, the present embodiments are to be considered as illustrative and not restrictive, and the invention is not to be limited to the details given herein, but may be modified within the scope and equivalents of the appended claims.

What is claimed is:

1. A processing chamber comprising:
a chamber top having at least one gas injection port;
one or more chamber sides, each of the chamber sides having side edges sealed to the side edges of adjacent sides and having a top edge sealed to the chamber top;
a chamber bottom, each of the plurality of chamber sides having a bottom edge bonded to the chamber bottom to enclose the process chamber;
a substrate support disposed in the processing chamber between the chamber top and the chamber bottom, the substrate support having a supporting surface disposed in a corresponding support surface plane;
an annular plenum disposed between the support surface plane and the chamber top, the plenum including:
at least one vacuum inlet port coupled to a gas pump down source;
a continuous inlet gap proximate to a perimeter of the substrate support, the continuous inlet gap having an inlet gas flow resistance of between about twice and about twenty times an outlet gas flow resistance the at least one vacuum inlet port.

2. The process chamber of claim 1, wherein the continuous inlet gap has a cross-sectional area less than a cross-sectional area of the at least one vacuum inlet port.

3. The process chamber of claim 1, wherein the continuous inlet gap has a depth greater than a width of the continuous inlet gap.

4. The process chamber of claim 1, wherein the at least one gas injection port is substantially centrally located in the chamber top.

5. The process chamber of claim 4, wherein a substantially uniform, azimuthally distributed gas flow path is defined between the at least one gas injection port in the chamber top and the continuous inlet gap.

6. The process chamber of claim 5, wherein a gas flow velocity in the substantially uniform, azimuthally distributed gas flow path has an azimuthal velocity variation of between about 0.0 meters per second and less than about 0.6 meters per second at the perimeter of the substrate support.

7. The process chamber of claim 1, wherein the continuous inlet gap having an inlet gas flow resistance of between about five and about twenty times an outlet gas flow resistance the at least one vacuum inlet port.

8. The process chamber of claim 1, wherein the continuous inlet gap having an inlet gas flow resistance of between about five and about ten times an outlet gas flow resistance the at least one outlet port.

9. The process chamber of claim 1, wherein the continuous inlet gap has a width of between about 1 and about 10 millimeters.

10. The process chamber of claim 1, wherein the continuous inlet gap has a depth between the inlet gap and the plenum of between about 5 and about 25 millimeters.

11. The process chamber of claim 1, wherein the plenum has a cross-sectional area greater than the cross-sectional area of the continuous inlet gap.

12. The process chamber of claim 1, wherein the at least one vacuum inlet port includes two vacuum inlet ports.

13. The process chamber of claim 1, wherein the at least one vacuum inlet port includes at least two vacuum inlet ports, wherein the at least two vacuum inlet ports are substantially evenly distributed around the perimeter of the annular plenum.

14. The process chamber of claim 1, wherein the at least one vacuum inlet port includes three vacuum inlet ports.

15. The process chamber of claim 1, wherein the annular plenum is included in the chamber top.

16. The process chamber of claim 1, wherein the annular plenum is formed by an extension extending from the chamber top and toward the plurality of chamber sides and wherein the continuous inlet gap is formed between the extension and the plurality of chamber sides.

17. The process chamber of claim 1, wherein the annular plenum is disposed between the chamber top and a plane of the substrate support.

18. A method of flowing gases through a processing chamber comprising:
inputting a gas flow into the processing chamber;
distributing the gas flow in a substantially even azimuthal distribution from the center portion of the top of the processing chamber to a continuous inlet gap disposed near a perimeter of the processing chamber wherein the continuous inlet gap has a gas flow resistance of at least twice a gas flow resistance of at least one vacuum inlet port disposed in the top of the processing chamber, wherein the continuous inlet gap is disposed between a substrate support plane and the processing chamber top.

19. The method of claim 18, wherein the continuous inlet gap is fluidly coupled to an annular plenum, the annular plenum including the at least one vacuum inlet port, the at least one vacuum inlet port being coupled to a gas pump down source capable of drawing the gas flow out of the processing chamber, through the continuous inlet gap, into the annular plenum and out through the at least one vacuum inlet port.
